(19) United States
(12) Patent Application Publication
(10) Pub. No.: US 2024/0179896 A1
(43) Pub. Date: May 30, 2024

(54) 1.5T OTP MEMORY DEVICE AND METHOD FOR FABRICATING SAME

(71) Applicant: HeFeChip Corporation Limited, Hong Kong (CN)

(72) Inventor: Geeng-Chuan CHERN, Cupertino, CA (US)

(21) Appl. No.: 18/089,063

(22) Filed: Dec. 27, 2022

(30) Foreign Application Priority Data
Nov. 29, 2022 (CN) 202211513349.6.

(51) Int. Cl. H10B 20/25; G11C 17/18

(52) U.S. Cl. CPC H10B 20/25; G11C 17/18

(57) ABSTRACT

A 1.5T one-time programmable memory device and a method for fabricating it re disclosed. The 1.5T OTP memory device includes at least one 1.5T memory cell formed in an active area of a semiconductor substrate. The 1.5T memory cell includes one select transistor and one half of a grounding transistor. This structure is simple. Moreover, in the grounding transistor, a portion of a thin gate dielectric layer is sandwiched between a doped junction region coupled to a source region in the select transistor and a grounding gate. During programming of the 1.5T memory cell, a voltage on the drain region in the select transistor can be coupled to the doped junction region to cause the thin gate dielectric layer portion sandwiched between the doped junction region and the grounding gate to rupture at a low programming voltage.

### CROSS-REFERENCE TO RELATED APPLICATION

This application claims the priority of Chinese patent application number 202211513349.6, filed on Nov. 29, 2022, the entire contents of which are incorporated herein by reference.

### TECHNICAL FIELD

The present invention relates to the field of semiconductor technology and, in particular, to a 1.5T OTP memory device and a method for fabricating the device.

### BACKGROUND

One-time programmable (OTP) memory technology has been used in post-silicon validation, memory repair, online field testing, secure information storage and other applications. For example, in a memory repair application, an address of a defective cell may be recorded in an OTP memory device, and when an externally provided address is found to be the same as the address of the defective cell, a semiconductor circuit may access a redundant memory cell rather than the defective one, thus achieving the purpose of repair. As another example, in order to address security threats to Internet of Things (IoT) devices, such as information leakage, unauthorized access, malware attacks or the like, information may be stored in OTP memory devices to be avoided from re-programming.

Programming of a conventional OTP memory device is accomplished by antifuses, which are constructed from two conductors and a dielectric layer sandwiched between them. The antifuse remains in a non-conductive state until the device is programmed. During programming, the dielectric layer ruptures under the action of a high voltage applied between the two conductors, resulting in a current and conductivity.

However, such conventional OTP memory devices are complicated in terms of structure and fabrication, increasing difficulties in chip area shrinkage and cost reduction. Moreover, a high programming current is required to cause rupturing of the dielectric layer between the conductors.

### SUMMARY OF THE INVENTION

In order to overcome the problems of structural and fabrication complexity and a high programming current required with the conventional OTP memory devices, the present invention provides a method for fabricating a 1.5T OTP memory device and such a 1.5T OTP memory device.

In one aspect, the present invention provides a method for fabricating a 1.5T OTP memory device, comprising:
providing a semiconductor substrate comprising an active area;
forming a gate dielectric layer on a surface of the semiconductor substrate;
forming an isolation material layer on the gate dielectric layer, and etching the isolation material layer to form an isolation element;
thickening a portion of the gate dielectric layer not covered by the isolation element to form a thick gate dielectric layer, with an unthickened portion of the gate dielectric layer serving as a thin gate dielectric layer;
narrowing the isolation element by etching to expose portions of the thin gate dielectric layer on opposite sides of the isolation element;
forming doped junction regions in the active area on the opposite sides of the isolation element;
forming a grounding gate covering the isolation element and the portions of the thin gate dielectric layer exposed on the opposite sides of the isolation element;
forming select gates on the thick gate dielectric layer on opposite sides of the grounding gate; and
forming source regions and drain regions in the active area, wherein the source region is located between the grounding gate and the select gates, wherein the drain region is located on the opposite side of the select gate with respect to the source regions, and wherein the source region is coupled to the doped junction region and has a same conductivity type as the doped junction region.

Optionally, the isolation element may be narrowed by using an isotropic wet etching.

Optionally, the portions of the thin gate dielectric layer exposed on the opposite sides of the isolation element may have an equal width.

Optionally, the widths of the portion of the thin gate dielectric layer exposed on the opposite sides of the isolation element may range from 2 nm to 100 nm.

Optionally, the isolation element may comprise at least one of silicon nitride, silicon oxynitride and silicon carbide.

Optionally, the thin gate dielectric layer may have a thickness ranging from 1 nm to 5 nm, and the thick gate dielectric layer may have a thickness ranging from 3 nm to 15 nm.

Optionally, forming the doped junction regions may comprise:
forming a patterned photoresist layer over the thick gate dielectric layer, the patterned photoresist layer exposing the isolation element, the portions of the thin gate dielectric layer on the opposite sides of the isolation element and portions of the thick gate dielectric layer adjacent to the thin gate dielectric layer;
performing a first phosphorus ion implantation with an energy of 30 KeV to 40 KeV at a dose of 5E12/cm² to 5E13/cm²; and
performing an arsenic ion implantation with an energy of 15 KeV to 30 KeV at a dose of 1E15/cm² to 5E15/cm².

Optionally, after forming the source regions and the drain regions, the method may further comprise:
removing portions of the thick gate dielectric layer exposed between the grounding gate and the select gate adjacent to the grounding gate, and forming a self-aligned metal silicide layer over the exposed surface of the semiconductor substrate and over surfaces of the grounding gate and the select gates;
forming an interlayer dielectric layer, which fills up gaps between the grounding gate and the select gates and covers the grounding gate and the select gates; and
forming a bit line on the interlayer dielectric layer, and connecting each drain region to the bit line by a corresponding contact plug extending through the interlayer dielectric layer.

In another aspect, the present invention provides a 1.5T OTP memory device, comprising at least one 1.5T memory cell formed in an active area of a semiconductor substrate, wherein each 1.5T memory cell comprises one select transistor and a half of a grounding transistor, wherein the select transistor comprises: a thick gate dielectric layer formed over the semiconductor substrate; a select gate formed on the thick gate dielectric layer; and a drain region and a source region, which are formed in the active area on opposite sides of the select gate, and wherein the grounding transistor comprises:
a thin gate dielectric layer;
an isolation element formed on the thin gate dielectric layer, the isolation element exposing portions of the thin gate dielectric layer on opposite sides thereof,
a grounding gate covering on the isolation element and the exposed portions of the thin gate dielectric layer; and
doped junction regions formed in the active area on the opposite sides of the isolation element, wherein the doped junction region is coupled to the source region in select transistor and has a same conductivity type as the source region.

Optionally, the 1.5T OTP memory device may comprise a plurality of pairs of the 1.5T memory cells to form a memory array, wherein the grounding gates in the plurality of pairs of the 1.5T memory cells are interconnected to form at least one grounding gate line, wherein the select gates in the plurality of pairs of the 1.5T memory cells are interconnected to form at least two word lines, and wherein the drain regions in the select transistors in the plurality of pairs of the 1.5T memory cells are interconnected to form at least one bit line.

The method provided in the present invention offers a simple, low-cost process, and the formed 1.5T OTP memory device features a simple layout. A word line located over an active area, together with a source region and a drain region on opposite sides thereof, constitutes a select transistor of a 1.5T memory cell, and a grounding gate line located over the active area provides a grounding transistor of the 1.5T memory cell, with a portion of a thin gate dielectric layer being sandwiched between a doped junction region proximate the source region and the grounding gate line. One-time programming of the 1.5T memory cell can be accomplished by coupling a voltage on the drain region in the select transistor to the doped junction region under the grounding transistor, so as to cause the portion of the thin gate dielectric layer sandwiched between the doped junction region and the grounding gate line to rupture at a low programming current.

The 1.5T OTP memory device provided in the present invention includes at least one 1.5T memory cell formed in an active area of a semiconductor substrate. The 1.5T memory cell includes one select transistor and one half of a grounding transistor. This structure is simple. Moreover, in the grounding transistor, a portion of a thin gate dielectric layer is sandwiched between a doped junction region proximate a source region in the select transistor and a grounding gate. During programming of the 1.5T memory cell, a voltage on the drain region in the select transistor can be coupled to the doped junction region to cause the thin gate dielectric layer portion sandwiched between the doped junction region and the grounding gate to rupture at a low programming current.

### BRIEF DESCRIPTION OF THE DRAWINGS

FIG. 1 is a schematic circuit diagram of a 1.5T OTP memory device according to an embodiment of the present invention.

FIG. 2 is a schematic plan view of a 1.5T OTP memory device according to an embodiment of the present invention.

FIGS. 3 to 8 are schematic cross-sectional views of structures resulting from steps in a method for fabricating a 1.5T OTP memory device according to an embodiment of the present invention.

FIG. 9 is a schematic circuit diagram of one pair of mirrored 1.5T memory cells in FIG. 8.

FIG. 10 is a schematic cross-sectional view of a 1.5T memory cell selected for programming and another 1.5T memory cell according to an embodiment of the present invention.

### DETAILED DESCRIPTION

1.5T one-time programmable (OTP) memory devices, as well as fabrication thereof, according to particular embodiments of the present invention will be described in greater detail below with reference to the accompanying drawings. Note that the figures are provided in a very simplified form not necessarily drawn to exact scale for the only purpose of facilitating easy and clear description of the embodiments. Additionally, the spatially relative terms are intended to encompass different orientations of the device in use or operation in addition to the orientation depicted in the figures. For example, if the device in the figures is inverted or otherwise oriented (e.g., rotated), the exemplary term “over” can encompass an orientation of “under” and other orientations. Throughout the drawings, if any component is identical to a labeled one, although such components may be easily identified in all the figures, in order for a more clear description of labels to be obtained, not all identical components are labeled and described in the following description and accompanying drawings.

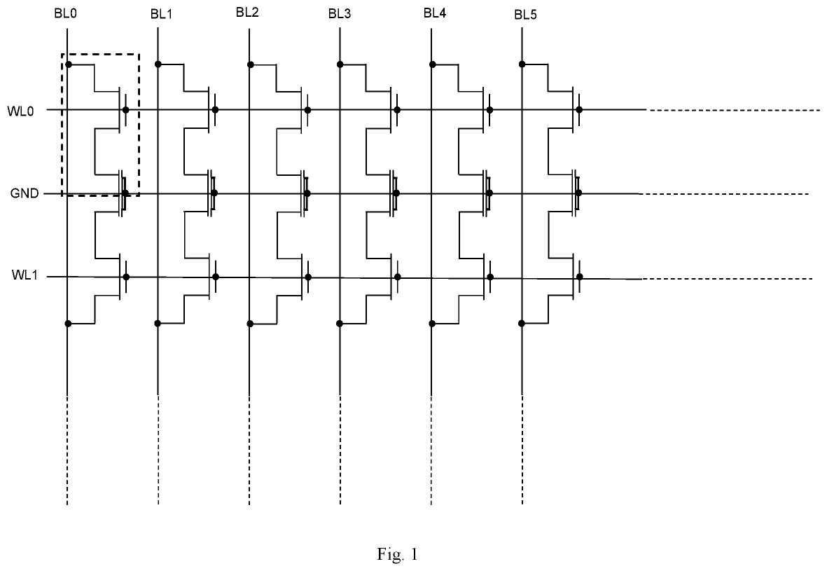

Embodiments of the present invention relate to a method for fabricating a 1.5T OTP memory device including at least one 1.5T memory cell formed in an active area of a semiconductor substrate. Each 1.5T memory cell includes one select transistor and one half of a grounding transistor (i.e., a total of 1.5 transistors, (1.5T)). The 1.5T OTP memory device may include a memory array including a plurality of such 1.5T memory cells, as shown in FIG. 1, where the dashed box indicates one of the 1.5T memory cells. The select transistors have gates (i.e., select gates) connected to word lines (WL0, WL1, . . . ), drain regions connected to bit lines (BL0, BL1, BL2, BL3, BL4, BL5 . . . ), and source regions connected to the grounding transistors. Gates of the grounding transistors (i.e., grounding gates) are connected to grounding gate lines (GND).

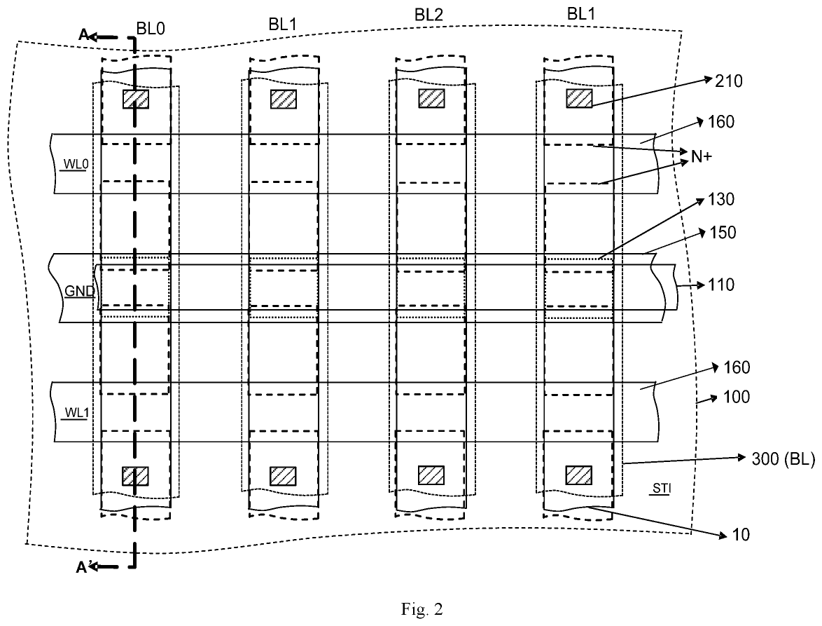

The method will be described below with reference to FIGS. 2 to 8, in which the cross-sectional views of FIGS. 3 to 8 are taken longitudinally along AA′ in FIG. 2.

Referring to FIGS. 2 and 3, first of all, a semiconductor substrate 100 is provided, which includes isolation (e.g., shallow trench isolation (STI)) regions and a plurality of active areas 10 defined by the isolation regions. The semiconductor substrate 100 may be a silicon substrate or another suitable substrate, such as an N-type doped silicon substrate (e.g., N-Si, with phosphorus or arsenic), or a P-type doped silicon substrate (e.g., P-Si, with boron, boron difluoride or indium). In the semiconductor substrate 100, N- or P-type doped well regions may be selectively formed. According to embodiments of the present invention, the 1.5T OTP memory cells may be formed on N-type or P-type doped regions of the semiconductor substrate 100. The following description is set forth in the context of the semiconductor substrate 100 being implemented as a P-type doped silicon (P-Si) substrate with N-channel transistors formed on a surface thereof as an example. It will be appreciated that the invention is also applicable to the case of P-channel transistors when the aforementioned N- and P-type components are replaced with P- and N-type ones, respectively.

Referring to FIG. 3, a gate dielectric layer 101 over a surface of the semiconductor substrate 100 and an isolation material layer 102 over the gate dielectric layer 101 are successively formed. Examples of a material from which the gate dielectric layer 101 is fabricated may include silica (SiO₂), silicon oxynitride (SiON), hafnia (HfO) and other suitable materials. In this embodiment, the material is implemented as silica, for example. Examples of a material from which the isolation material layer 102 is fabricated may include silicon nitride (Si₃N₄), silicon oxynitride (SiON), silicon carbide (SiC) and other suitable materials. Here, the isolation material layer 102 is, for example, a silicon nitride layer having a thickness of about 50 nm to 200 nm. As needed, after the gate dielectric layer 101 is formed and before the isolation material layer 102 is deposited, ions may be implanted into channel regions of the semiconductor substrate 100 to adjust a threshold voltage (Vth) of the transistors to be fabricated. As an example, boron (B) or boron difluoride (BF₂) may be implanted with an energy of 10 KeV to 20 KeV at a dose of 1E12/cm² to 1E13/cm².

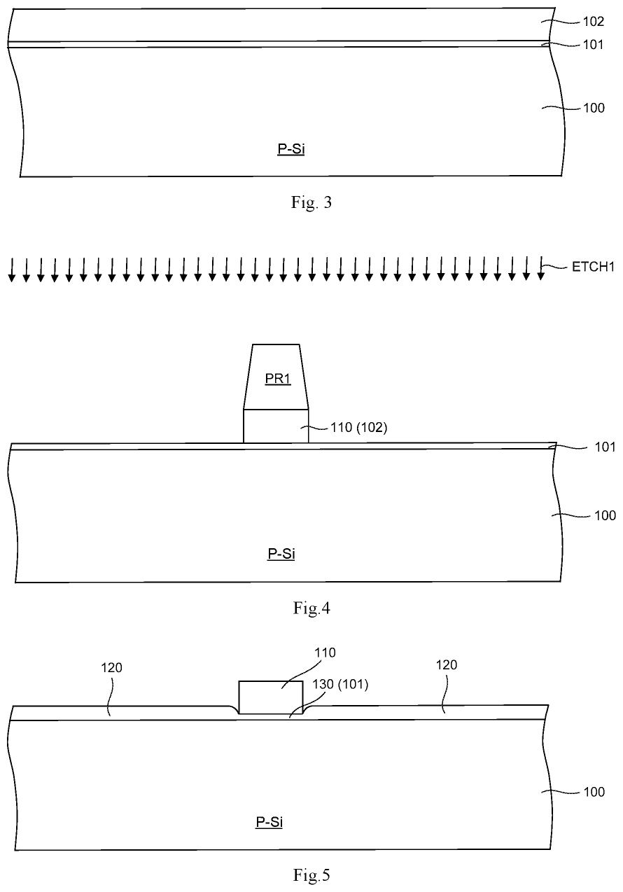

Referring to FIGS. 2 and 4, at least one isolation element 110 is then formed by etching the isolation material layer 102. Each isolation element 110 extends on a surface of the gate dielectric layer 101 to traverse several of the aforementioned active areas 10 of the semiconductor substrate 100. Specifically, a patterned photoresist layer PR1 defining a location for the isolation element 110 may be first formed on the isolation material layer 102 by a photolithography process, and an anisotropic dry etching process ETCH1 may be then carried out to remove the exposed portion of the isolation material layer 101, followed by removal of the photoresist layer PR1.

Referring to FIGS. 2 and 5, the gate dielectric layer 101 uncovered by the isolation element 110 is thickened. Hereinafter, the thickened gate dielectric layer 101 is referred to as the thick gate dielectric layer 120, while the unthickened gate dielectric layer 101 (covered by the isolation element 110) is referred to as the thin gate dielectric layer 130. As an example, a thickness of the gate dielectric layer 101 uncovered by the isolation element 110 may be increased by 2 nm to 10 nm using a local oxidation technique. The thickness of the thin gate dielectric layer 130 may range from 1 nm to 5 nm, for example. The thickness of the thick gate dielectric layer 120 may range from 3 nm to 15 nm, for example.

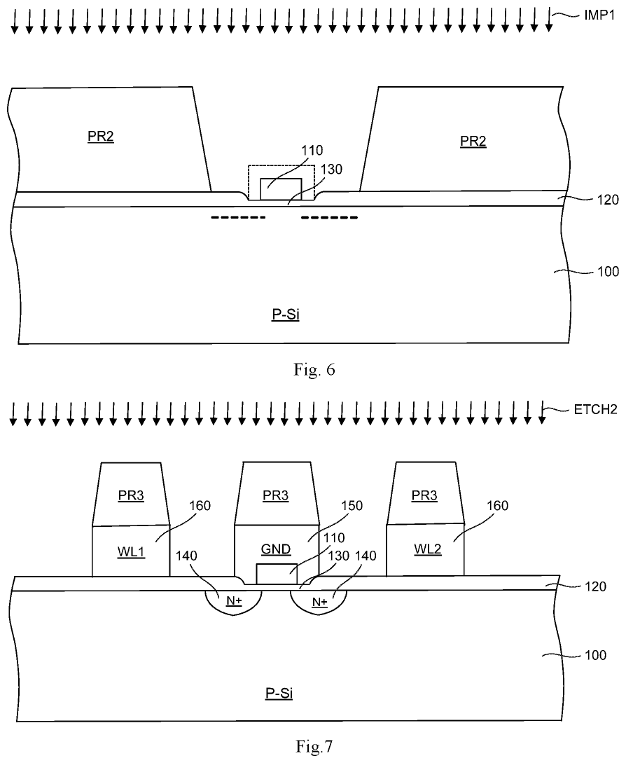

Referring to FIG. 6, the isolation element 110 (overlying the thin gate dielectric layer 130) is then etched and narrowed so that portions of the thin gate dielectric layer 130 on opposite sides of the processed isolation element 110 are exposed. The isolation element 110 may be narrowed as a result of overall shrinkage thereof achieved by an isotropic etching process (e.g., an isotropic wet etching process). The portions of the thin gate dielectric layer 130 exposed on opposite sides of the narrowed isolation element 110 may have a same width. This process can result in a self-aligned thin gate dielectric layer 130 with a predetermined width, without involving the use of any photomask. It is simple and can provide cost savings. An exposed width of the thin gate dielectric layer 130 may be flexibly adjusted by changing the amount of the material of the isolation element 110 that is etched away. As an example, the portions of the thin gate dielectric layer 130 exposed on opposite sides of the isolation element 110 have a width in the range of 2 nm to 100 nm. In this embodiment, a wet etching process using phosphoric acid may be employed to etch the isolation element 110 that is made of silicon nitride. As an example, this etching step may result in 30-70% shrinkage of the isolation element 110 (the dotted box marked around the isolation element 110 in FIG. 6 represents an outer contour of the isolation element 110 before etched).

Referring to FIGS. 6 and 7, the method further includes the step of implanting ions into active areas 10 on opposite sides of the isolation element 110, resulting in the formation of doped junction regions 140. The doped junction regions 140 are of an opposite conductivity type to that of the semiconductor substrate 100. Here, the doped junction regions 140 are N-type regions, in particular heavily doped N-type (N+) regions. The doped junction regions 140 are preferred to be graded junctions to increase the rupture voltage. The doped junction regions 140 are formed under the thin gate dielectric layer 130 exposed in the aforementioned step of narrowing the isolation element 110 in order to enable rupturing of the portions of the thin gate dielectric layer 130 exposed from the narrowed isolation element 110 at a reduced programming current during programming of the 1.5T memory cell.

Referring to FIGS. 6 and 7, as an example, in order to fabricate the doped junction regions 140, at first, a patterned photoresist layer PR2 is formed on the thick gate dielectric layer 120, which defines ion implantation regions for the doped junction regions 140. Specifically, the isolation element 110, the thin gate dielectric layer 130 on opposite sides of the isolation element 110 and portions of the thick gate dielectric layer 120 proximate the thin gate dielectric layer 130 are exposed from the photoresist layer PR2. N-type ions are then implanted IMP1 into the portions of the active areas 10 indicated by the thick dashed lines in FIG. 6. The implantation IMP1 may be accomplished, for example, in two steps. As an example, in the first step, phosphorus ions may be implanted with energy of 30 KeV to 40 KeV at a dose of 5E12/cm² to 5E13/cm². In the second step, arsenic ions may be implanted with energy of 15 KeV to 30 KeV at a dose of 1E15/cm² to 5E15/cm². After the completion of the implantation IMP1, removal of the photoresist layer PR2 may be followed by a rapid thermal annealing (RTA) or furnace annealing process, resulting in the formation of the doped junction regions 140. Referring to FIG. 7, in this embodiment, the doped junction regions 140 are formed in the active areas 10 on opposite sides of the isolation element 110. Each doped junction region 140 extends from a position under the thin gate dielectric layer 130 on one side of the isolation element 110 to a position under the thick gate dielectric layer 120 proximate the thin gate dielectric layer 130.

Referring to FIGS. 2 and 7, for each isolation element 110, a grounding gate line 150 and word lines (WL) 160 on opposite sides of the grounding gate line are formed. Specifically, this may include depositing, over the semiconductor substrate 100, a gate material layer (with a thickness of about 80 to 150 nm), which may be, for example, N-type doped polysilicon, silicide, metal or another suitable material. A patterned photoresist layer PR3 may be then formed on the gate material layer, which defines locations for the grounding gate line and the word lines. In this embodiment, the grounding gate line and the word lines serve as gates for 1.5T memory cells in the memory device, and the photoresist layer PR3 defines locations for these gates. After that, an anisotropic etching process ETCH2 is employed to remove the portions of the gate material layer exposed from the photoresist layer PR3, followed by removal of the photoresist layer PR3. In this embodiment, as a result of this step, at least one grounding gate line 150 and at least two word lines 160 are formed. Each of the grounding gate line 150 and the word lines 160 traverses several of the active areas 10 of the semiconductor substrate 100. For each isolation element 110, the grounding gate line 150 is so formed as to cover the isolation element 110 and a portion of the thin gate dielectric layer 130 exposed on opposite sides of the isolation element 110, and the word lines 160 are formed on opposite sides of the grounding gate line 150, in particular on the thick gate dielectric layer 120. Thus, an electrical path from doped junction regions 140 to the grounding gate line 150 would be limited in the portion of the thin gate dielectric layer 130 exposed on opposite sides of the isolation element 110, wherein the portion of the thin gate dielectric layer 130 further forms a breakdown voltage zone.

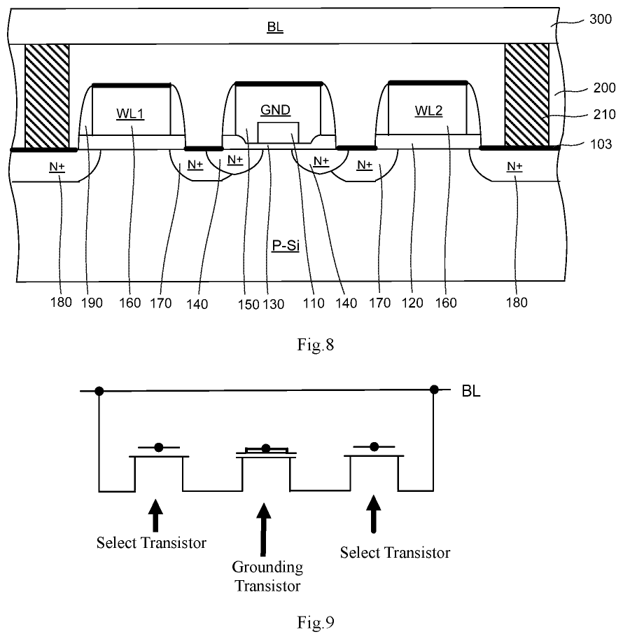

Referring to FIG. 8, source regions 170 and drain regions 180 are then formed in the active areas 10. The source regions 170 are formed between the grounding gate line 150 and the word lines 160 on opposite sides thereof, and the drain regions 180 are formed on the other sides of the word lines 160 with respect to the source regions 170. The source regions 170 and the doped junction regions 140 are coupled and have the same conductivity type (here, both are N+).

Subsequent to the formation of the grounding gate line 150 and the word lines 160 and prior to the formation of the source regions 170 and the drain regions 180, lightly doped drain (LDD) regions (not shown) may be formed in the active areas 10 of the semiconductor substrate 100. The LDD region is located between the grounding gate line 150 and the word lines 160 on opposite sides thereof and on the sides of the word lines 160 away from the grounding gate line 150. Spacers 190 are formed on opposite sidewalls of the grounding gate line 150 and of the word lines 160. In this embodiment, the source regions 170 and the drain regions 180 may be heavily doped N-type regions formed by implanting N-type ions into portions of the active areas 10 between the grounding gate line 150 and the word lines 160 on opposite sides thereof and on the sides of the word lines 160 away from the grounding gate line 150 with energy of, for example, 20 KeV to 50 KeV at a dose of, for example, 2E15 cm⁻² to 8E15 cm⁻².

Referring to FIG. 8, subsequent to the formation of the source regions 170 and the drain regions 180, the method may further include: removing portions of the thick gate dielectric layer 120 exposed on opposite sides of the grounding gate line 150 and of the word lines 160, and forming a self-aligned metal silicide layer 103 on exposed surfaces of the semiconductor substrate 100, of the grounding gate line 150 and of the word lines 160; then forming an interlayer dielectric layer 200, which fills up gaps between the grounding gate line 150 and the word lines 160 and covers the grounding gate line 150 and the word lines 160; and subsequently, forming at least one bit line (BL) 300 on the interlayer dielectric layer 200 and each drain region 180 is connected to corresponding bit line 300 by contact plugs 210 extending through the interlayer dielectric layer 200.

As a result of the above steps, a 1.5T OTP memory device as shown in FIG. 2 may be formed, which includes at least one 1.5T memory cell. This method offers a simple, low-cost process, and the formed 1.5T OTP memory device features a simple layout. Referring to FIGS. 2, 8 and 9, in the 1.5T OTP memory device made by the method, the word lines 160 located over the active areas 10, together with the source regions 170 and the drain regions 180 on opposite sides thereof, constitute select transistors of the 1.5T memory cells, and the grounding gate line 150 over the active areas 10 provides grounding transistors of the 1.5T memory cells, with portions of the thin gate dielectric layer 130 being sandwiched between the doped junction regions 140 coupled to the source regions 170 and the grounding gate line 150. One-time programming of a given 1.5T memory cell can be accomplished by coupling a voltage on the drain region in the select transistor to the doped junction region under the grounding transistor, to cause the portion of the thin gate dielectric layer sandwiched between the doped junction region and the grounding gate line to rupture at a low programming voltage.

Embodiments of the present invention include a 1.5T OTP memory device, which can be made using the above method. Referring to FIGS. 1 to 2 and 8 to 9, the 1.5T OTP memory device includes at least one 1.5T memory cell formed in an active area 10 of a semiconductor substrate 100. Each 1.5T memory cell includes one select transistor and one half of a grounding transistor. The select transistor includes: a thick gate dielectric layer 120 formed over the semiconductor substrate 100; a select gate formed on the thick gate dielectric layer 120 (which may be provided by a word line 160); and a drain region 180 and a source regions 170, which are formed in the active area 10 on opposite sides of the select gate. The grounding transistor includes a thin gate dielectric layer 130, an isolation element 110 and a grounding gate (which may be provided by a grounding gate line 150). The isolation element 110 is formed on the thin gate dielectric layer 130, and portions of the thin gate dielectric layer 130 are exposed on opposite sides of the isolation element 110. The grounding gate covers the isolation element 110 and the exposed portions of the thin gate dielectric layer 130. The grounding transistor further includes a doped junction regions 140 formed in the active area 10 on opposite sides of the isolation element 110. The source region 170 of the select transistor and the doped junction regions 140 are coupled and have the same conductivity type.

In another aspect, the 1.5T OTP memory device may include multiple pairs of 1.5T memory cells. Each pair has two 1.5T memory cells which comprise two select transistors and one grounding transistor, wherein the two select transistors are configured in a mirrored arrangement and the grounding transistor is shared by the two 1.5T memory cells. The multiple pairs may make up a memory array, in which the grounding gates therein may be interconnected to form at least one grounding gate line (GND) 150, the select gates therein may be interconnected to form at least two word lines (WL) 160, and the drain regions 180 in the select transistors thereof may be interconnected to form at least one bit line (BL) 300. The drain regions 180 in each mirrored pair are connected to the same bit line 300.

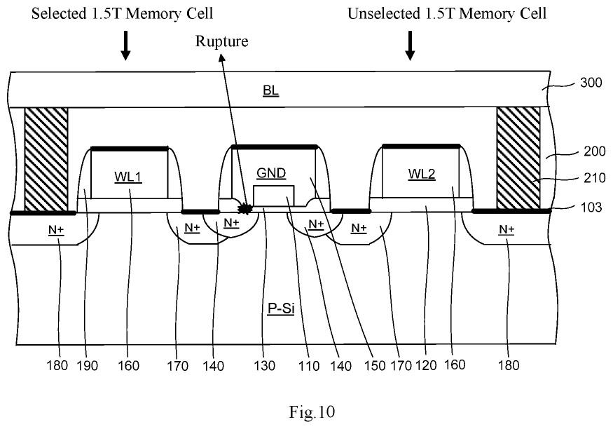

One-time programming and reading of the 1.5T OTP memory device will be described below with reference to FIG. 10. In the memory array of FIG. 2, a particular 1.5T memory cell may be selected for a programming or reading operation by applying predetermined bias voltages to associated word and bit lines. Here, as an example, the 1.5T memory cell on the left in FIG. 10 is selected for a programming or reading operation and referred to hereinafter as the selected 1.5T memory cell, while the 1.5T memory cell on the right is unselected and referred to hereinafter as the unselected 1.5T memory cell.

Table 1 presents biasing conditions for a programming operation performed on the selected 1.5T memory cell according to an embodiment of the present invention. Referring to Table 1, the programming operation includes: applying a first specified voltage (e.g., 3-10 V) to the drain region 180 of the selected 1.5T memory cell via the associated bit line (BL) 300 and applying a second specified voltage (e.g., 3-10 V) to the gate of the select transistor in the selected 1.5T memory cell via the associated word line (WL) 160, with any remaining word line 160 being grounded, any remaining bit line 300 being grounded or floating and the semiconductor substrate 100 being grounded. Under the action of the first and second specified voltages, a channel in the select transistor in the selected 1.5T memory cell is turned on, coupling the first specified voltage to the source region 170. Since the source region 170 is coupled to the doped junction region 140, and the grounding gate 150 is grounded (GND), the thin gate dielectric layer 130 sandwiched between the doped junction region 140 and the grounding gate 150 permanently ruptures under the effect of the first specified voltage (as indicated by “Rupture” in FIG. 10), establishing a conductive path.

TABLE 1
Biasing Conditions for Programming

| Terminal | Bias | |
|---|---|---|
| Selected WL | 3-10 | V |
| Unselected WL | 0 | V |
| Selected BL | 3-10 | V |
| Unselected BL | 0 V or floating | |
| Semiconductor substrate | 0 | V |

TABLE 2
Biasing Conditions for Reading

| Terminal | Bias | |
|---|---|---|
| Selected WL | 1-3 | V |
| Unselected WL | 0 | V |
| Selected BL | 0.5-1.5 | V |
| Unselected BL | 0 V or floating | |
| Semiconductor substrate | 0 | V |

Table 2 summarizes biasing conditions for a reading operation performed on the selected 1.5T memory cell according to an embodiment of the present invention. Referring to Table 2, the programming operation includes: applying a third specified voltage (e.g., 0.5-1.5 V) to the drain region 180 of the selected 1.5T memory cell via the associated bit line (BL) 300, and applying a fourth specified voltage (e.g., 1-3 V) to the gate of the select transistor in the selected 1.5T memory cell via the associated word line (WL) 160. In case that the selected 1.5T memory cell has been programmed and therefore a conductive path has been established in the thin gate dielectric layer 130 between the doped junction region 140 and the grounding gate 150, under the action of the third and the fourth specified voltages, a cell current will flow from the drain region 180 through the channel, the source regions 170 and the doped junction region 140 to the grounding gate 150. In case that the selected 1.5T memory cell has not been programmed and therefore the thin gate dielectric layer 130 sandwiched between the doped junction regions 140 and the grounding gate 150 has not ruptured, and as blocked by the thin gate dielectric layer 130, there will be no such cell current generated. Therefore, it can be determined whether the selected 1.5T memory cell has been programmed by detecting the presence of the cell current. If the cell current is detectable, then it is determined that the 1.5T memory cell is in a programmed state (state “1”). If no such cell current can be detected, then it is determined that the 1.5T memory cell is in a non-programmed state (state “0”).

The 1.5T OTP memory device provided in the present invention includes at least one 1.5T memory cell formed in an active area 10 of a semiconductor substrate 100. The 1.5T memory cell includes one select transistor and one half of a grounding transistor. This structure is simple. Moreover, in the grounding transistor, a portion of a thin gate dielectric layer 130 is sandwiched between a doped junction region 140 coupled to a source region 170 in the select transistor and a grounding gate 150. During programming of the 1.5T memory cell, a voltage on the drain region 180 in the select transistor can be coupled to the doped junction region 140 and cause the thin gate dielectric layer portion sandwiched between the doped junction region 140 and the grounding gate 150 to rupture at a low programming current.

It is to be noted that the embodiments disclosed herein are described in a progressive manner, with the description of each embodiment focusing on its differences from others. Reference can be made between the embodiments for their identical or similar parts.

The foregoing description is merely that of several preferred embodiments of the present invention and is not intended to limit the scope of the claims of the invention in any way. Any person of skill in the art may make various possible variations and changes to the disclosed embodiments in light of the methodologies and teachings disclosed hereinabove, without departing from the spirit and scope of the invention. Accordingly, any and all such simple variations, equivalent alternatives and modifications made to the foregoing embodiments based on the essence of the present invention without departing from the scope of the embodiments are intended to fall within the scope of protection of the invention.

What is claimed is:

1. A method for fabricating a 1.5T one-time programmable memory device including at least one pair of 1.5T memory cells, comprising:
providing a semiconductor substrate comprising an active area;
forming a gate dielectric layer over a surface of the semiconductor substrate;
forming an isolation material layer over the gate dielectric layer and etching the isolation material layer to form an isolation element;
thickening a portion of the gate dielectric layer not covered by the isolation element to form a thick gate dielectric layer, with an unthickened portion of the gate dielectric layer serving as a thin gate dielectric layer;
narrowing the isolation element by etching to expose portions of the thin gate dielectric layer on opposite sides of the isolation element;
forming doped junction regions in the active area on the opposite sides of the isolation element;
forming a grounding gate covering the isolation element and the portions of the thin gate dielectric layer exposed on the opposite sides of the isolation element;
forming select gates on the thick gate dielectric layer on opposite sides of the grounding gate; and
forming source regions and drain regions in the active area, wherein the source region is located between the grounding gate and the select gate, wherein the drain region is located on an opposite side of the select gate with respect to the source region, and
wherein the source region is coupled to the doped junction region and has a same conductivity type as the doped junction region.

2. The method of claim 1, wherein the isolation element is narrowed by using an isotropic wet etching.

3. The method of claim 1, wherein the portions of the thin gate dielectric layer exposed on the opposite sides of the isolation element have an equal width.

4. The method of claim 3, wherein the width of the portions of the thin gate dielectric layer exposed on the opposite sides of the isolation element ranges from 2 nm to 100 nm.

5. The method of claim 1, wherein the isolation element comprises at least one of silicon nitride, silicon oxynitride and silicon carbide.

6. The method of claim 1, wherein the thin gate dielectric layer has a thickness ranging from 1 nm to 5 nm; and the thick gate dielectric layer has a thickness ranging from 3 nm to 15 nm.

7. The method of claim 1, wherein forming the doped junction regions comprises:
forming a patterned photoresist layer over the thick gate dielectric layer, the patterned photoresist layer exposing the isolation element, the portions of the thin gate dielectric layer on the opposite sides of the isolation element and portions of the thick gate dielectric layer adjacent to the thin gate dielectric layer;
performing a first phosphorus ion implantation with an energy of 30 KeV to 40 KeV at a dose of 5E12/cm² to 5E13/cm²; and
performing an arsenic ion implantation with an energy of 15 KeV to 30 KeV at a dose of 1E15/cm² to 5E15/cm².

8. The method of claim 1, further comprising, after forming the source regions and the drain regions:
removing portions of the thick gate dielectric layer exposed between the grounding gate and the select gate adjacent to the grounding gate, and forming a self-aligned metal silicide layer over the exposed surface of the semiconductor substrate and over surfaces of the grounding gate and the select gates;
forming an interlayer dielectric layer, which fills up gaps between the grounding gate and the select gates and covers the grounding gate and the select gates; and
forming a bit line on the interlayer dielectric layer, and connecting each drain region to the bit line by a corresponding contact plug extending through the interlayer dielectric layer.

9. A 1.5T one-time programmable memory device, comprising at least one 1.5T memory cell formed in an active area of a semiconductor substrate, wherein each 1.5T memory cell comprises one select transistor and a half of a grounding transistor,
wherein the select transistor comprises:
a thick gate dielectric layer formed over the semiconductor substrate;
a select gate formed on the thick gate dielectric layer; and
a drain region and a source region, which are formed in the active area on opposite sides of the select gate, and
wherein the grounding transistor comprises:
a thin gate dielectric layer;
an isolation element formed on the thin gate dielectric layer, the isolation element exposing portions of the thin gate dielectric layer on opposite sides thereof,
a grounding gate covering the isolation element and the exposed portions of the thin gate dielectric layer; and
doped junction regions formed in the active area on the opposite sides of the isolation element, wherein the doped junction region is coupled to the source region in the select transistor and has a same conductivity type as the source region.

10. The 1.5T one-time programmable memory device of claim 9, comprising a plurality of pairs of the 1.5T memory cells to form a memory array, wherein the grounding gates in the plurality of pairs of the 1.5T memory cells are interconnected to form at least one grounding gate line, wherein the select gates in the plurality of pairs of the 1.5T memory cells are interconnected to form at least two word lines, and wherein the drain regions in the select transistors in the plurality of pairs of the 1.5T memory cells are interconnected to form at least one bit line.
